(19) United States
(12) Patent Application Publication
(10) Pub. No.: US 2022/0372625 A1
(43) Pub. Date: Nov. 24, 2022

(54) Apparatus and Method for Producing Carbon Nanotubes

(71) Applicant: MEIJO NANO CARBON CO., LTD, Aichi (JP)

(72) Inventors: Takeshi Hashimoto, Aichi (JP); Kei Takano, Aichi (JP)

(73) Assignee: MEIJO NANO CARBON CO., LTD, Aichi (JP)

(21) Appl. No.: 17/874,481

(22) Filed: Jul. 27, 2022

Related U.S. Application Data
(62) Division of application No. 15/765,003, filed on Mar. 30, 2018.

(30) Foreign Application Priority Data
Oct. 1, 2015 (JP) 2015-196221

(51) Int. Cl. C23C 16/52; C23C 16/26; C01B 32/16

(52) U.S. Cl. CPC C23C 16/52; C23C 16/26; C01B 32/16

(57) ABSTRACT

A CNT production apparatus 1 provided by the present invention includes a cylindrical chamber 10 and a control valve 60 provided to a gas discharge pipe 50. The chamber 10 includes a reaction zone provided in a partial range of the chamber 10 in the direction of the cylinder axis, a deposition zone 22 which is provided downstream of the reaction zone 20, and a deposition state detector 40 that detects a physical property value indicating a deposition state of carbon nanotubes in the deposition zone 22. The apparatus is configured to close the control valve 60 and deposit carbon nanotubes in the deposition zone 22 when the physical property value detected by the deposition state detector 40 is equal to or less than a predetermined threshold value, and configured to open the control valve 60 and recover the carbon nanotubes deposited in the deposition zone 22 when the physical property value exceeds the predetermined threshold value.

### TECHNICAL FIELD

This application is a Divisional of U.S. application Ser. No. 15/765,003 filed on Mar. 30, 2018, which is a National Stage of International Application No. PCT/JP2016/079159 filed on Sep. 30, 2016, which claims priority to Japanese Application No. 2015-196221 filed on Oct. 1, 2015, the content of which are hereby incorporated by reference in their entirety.

The present invention relates to a technique for producing carbon nanotubes by a so-called chemical vapor deposition (CVD) method.

The present international application claims priority based on Japanese Patent Application No. 2015-196221 filed on Oct. 1, 2015, the entire contents of which are incorporated herein by reference.

### BACKGROUND ART

Carbon nanotubes (hereinafter sometimes referred to as “CNT”) are a new material which has attract attention from many fields because CNT have excellent properties such as electric conductivity, thermal conductivity and mechanical strength. CNT are generally synthesized by placing carbon or a raw material including carbon, optionally in the presence of a catalyst, under high temperature conditions. A laser evaporation method, an arc discharge method and a chemical vapor deposition method are known as main producing methods. Among them, the chemical vapor deposition method (that is, the CVD method) synthesizes CNT by thermally decomposing a carbon-containing raw material (carbon source). Patent Literature 1 exemplifies a related art document relating to the production of CNT by the CVD method. Patent Literature 1 relates to a technique of a flowing gas-phase CVD method for producing CNT in a flowing gas phase.

### CITATION LIST

### Patent Literature

[PLT 1] Japanese Patent Application Publication No. 2013-35750

### SUMMARY OF INVENTION

Here, it would be useful to provide a technique for producing CNT of higher quality at a high yield by using the flowing gas-phase CVD method. It is an object of the present invention to provide a CNT production apparatus capable of solving such a problem. Another object of the present invention is to provide a CNT producing method capable of solving the above problem.

The present invention provides a carbon nanotube producing apparatus for generating carbon nanotubes. This apparatus includes: a cylindrical chamber; a carbon source supply unit which supplies a carbon source to the chamber from a carbon source supply port opened to the chamber; a gas supply unit which supplies a non-oxidizing gas to the chamber from a gas supply port opened to the chamber; a gas discharge pipe which is configured to be capable of discharging gas in the chamber from a gas release port; and a control valve which is provided to the gas discharge pipe. The chamber has: a reaction zone provided in a partial range of the chamber in a direction of a cylinder axis, and heated to a temperature at which carbon nanotubes are generated; a deposition zone which is provided downstream of the reaction zone and upstream of the gas release port, and in which the generated carbon nanotubes are cooled and deposited; and a deposition state detector which detects a physical property value indicating a deposition state of carbon nanotubes in the deposition zone. When the physical property value indicating the deposition state of carbon nanotubes detected by the deposition state detector is equal to or less than a predetermined threshold value, the apparatus is configured to close the control valve so that the carbon nanotubes are deposited in the deposition zone, and when the physical property value exceeds the predetermined threshold value, the apparatus is to open the control valve so that the carbon nanotubes deposited in the deposition zone are recovered.

Here, “carbon nanotube (CNT)” means a tubular carbon allotrope (typically, a cylindrical structural body having a graphite structure), and is not limited to a special form (length and diameter). The so-called single layer CNT, multilayer CNT, or a carbon nanohorns having an angular tube tip are typical examples included in the concept of CNT. The technique disclosed herein can be particularly advantageously used in the production of single-walled CNT. In this specification, “upstream” in the CNT production apparatus means upstream of the gas flow from the gas supply port to the gas release port, and “downstream” means downstream of the gas flow from the gas supply port to the gas release port.

With the apparatus of such a configuration, by closing the control valve and causing the deposition of the CNT in the deposition zone (typically, the attachment to the inner wall of the chamber), the carbon source can be better retained in the reaction zone upstream of the deposition zone (that is, diffusion to the downstream side of the reaction zone can be suppressed), and high-quality CNT can be efficiently generated (for example, in high yield) from the carbon source. Further, CNT can be produced continuously by opening the control valve and recovering the CNT deposited in the deposition zone when the deposition of CNT proceeds to some extent in the deposition zone. That is, the apparatus of the abovementioned configuration is suitable for continuous production of CNT.

In a preferred embodiment of the apparatus disclosed herein, a recovery unit for recovering the carbon nanotubes is further provided. The recovery unit is disposed downstream of the deposition zone and upstream of the gas release port. With such a configuration, while the gas discharge gas moves from the deposition zone to the gas release port, the CNT similarly moving from the deposition zone to the gas release port are recovered in the recovery part. Therefore, CNT can be efficiently recovered.

In a preferred embodiment of the apparatus disclosed herein, the recovery unit is disposed below the chamber. Further, the recovery unit is configured such that the carbon nanotubes deposited in the deposition zone fall into the recovery unit. In this way, CNT can be recovered more efficiently by causing the CNT to drop under gravity together with the flow of the gas discharge gas.

In a preferred embodiment of the apparatus disclosed herein, the physical property value indicating the deposition state of the carbon nanotubes is a pressure in the chamber. In this way, it is possible to easily grasp the deposition state of CNT in the deposition zone.

In a preferred embodiment of the apparatus disclosed herein, the carbon source supply port is disposed in the reaction zone (a region heated to a temperature at which CNT are generated when the CNT are produced, that is, when the carbon source is supplied from the supply port) or in the vicinity thereof. By using a configuration in which the carbon source is thus directly supplied to the high-temperature region, it is possible to generate CNT more efficiently from the carbon source. Further, such a configuration is also advantageous for gasifying (vaporizing) in a short time a carbon source liquid supplied from the carbon source supply port when a material which is liquid at normal temperature is used as the carbon source. Therefore, the configuration can also be preferably used for the production of CNT using such a material as a carbon source. In particular, the configuration is advantageous as a apparatus for producing CNT by using a material (for example, toluene) which is liquid at room temperature as the carbon source.

In a preferred embodiment of the apparatus disclosed herein, the carbon source supply unit is provided with a carbon source introduction pipe extending in the reaction zone and connected to the carbon source supply port (preferably disposed in the reaction zone or in the vicinity thereof). With such a configuration, the heat of the reaction zone is transferred from the carbon source supply port to the carbon source in the introduction pipe through the wall surface of the carbon source introduction pipe, whereby the carbon source (liquid) supplied from the carbon source supply port can be gasified in a short time. This is advantageous for continuously operating the apparatus (that is, continuously producing CNT). For example, CNT can be suitably produced over a longer period of time. When a liquid (for example, toluene) is used as the carbon source at room temperature, the effect obtained by using the abovementioned configuration can be exerted particularly well.

In a preferred embodiment of the apparatus disclosed herein, the gas supply unit is provided with a gas supply pipe extending in the reaction zone and connected to the gas supply port. The gas supply pipe and the carbon source introduction pipe have a double-pipe structure in which the gas supply pipe is an outer pipe and the carbon source introduction pipe is an inner pipe. In this way, the non-oxidizing gas supplied from the gas supply port comes into contact with the carbon source (liquid) supplied from the carbon source supply port, and the gasification and diffusion of the carbon source are promoted. This makes it possible to better disperse the gasified carbon source in the reaction zone. Therefore, higher quality CNT can be generated with good efficiency (for example, in high yield).

In a preferred embodiment of the apparatus disclosed herein, the gas supply unit is configured to supply the carbon source gas together with a non-oxidizing gas from the gas supply port to the chamber. With such a configuration, it is possible to efficiently generate CNT with a uniformly controlled diameter (for example, 2 nm or less, typically about 1 nm to 2 nm).

The present invention also provides a method for producing carbon nanotubes by which carbon nanotubes are generated by supplying a carbon source and a non-oxidizing gas to a cylindrical chamber, with the chamber being provided with a reaction zone which is provided in a partial range of the chamber in a direction of a cylinder axis and heated to a temperature at which carbon nanotubes are generated, a deposition zone which is provided downstream of the reaction zone and upstream of a gas release port for releasing gas in the chamber and in which the generated carbon nanotubes are cooled and deposited, and a deposition state detector which detects a physical property value indicating a deposition state of the carbon nanotubes in the deposition zone,

the method including the following steps of:

closing a control valve of a gas discharge pipe connected to the gas release port and depositing carbon nanotubes in the deposition zone when the physical property value indicating a deposition state of carbon nanotubes in the deposition zone is equal to or less than a predetermined threshold value (deposition step); and

opening the control valve and recovering the carbon nanotubes deposited in the deposition zone when the physical property value exceeds the predetermined threshold value (recovery step).

With such a method, high-quality CNT can be obtained continuously and efficiently (for example, in high yield) by repeating the deposition step and the recovery step.

In a preferred embodiment, a recovery unit is disposed below the chamber. In the step of recovering the carbon nanotubes, the carbon nanotubes deposited in the deposition zone may be caused to fall into the recovery unit. In yet another preferred embodiment, the physical property value indicating the deposition state of the carbon nanotubes is a pressure in the chamber.

### BRIEF DESCRIPTION OF DRAWINGS

FIG. 1 is a schematic diagram showing an example of a CNT production apparatus according to an embodiment.

FIG. 2 is a control flow diagram of a CNT production apparatus according to an embodiment.

### DESCRIPTION OF EMBODIMENTS

Embodiments of the present invention will be described below with reference to the drawings. In the following drawings, the same reference numerals are attached to members and parts that exhibit the same action. The dimensional relationship (length, width, thickness, etc.) in each drawing does not reflect the actual dimensional relationship. Further, matters other than those particularly mentioned in the present specification and necessary for the implementation of the present invention (for example, general matters relating to a CVD method such as a specific operation method for adjusting the reaction conditions such as the temperature and pressure of the reaction zone, and the like) can be grasped as design matters by a person skilled in the art on the basis of the related art in the pertinent field. The present invention can be carried out based on the contents disclosed in this specification and technical common sense in the pertinent field.

### First Embodiment

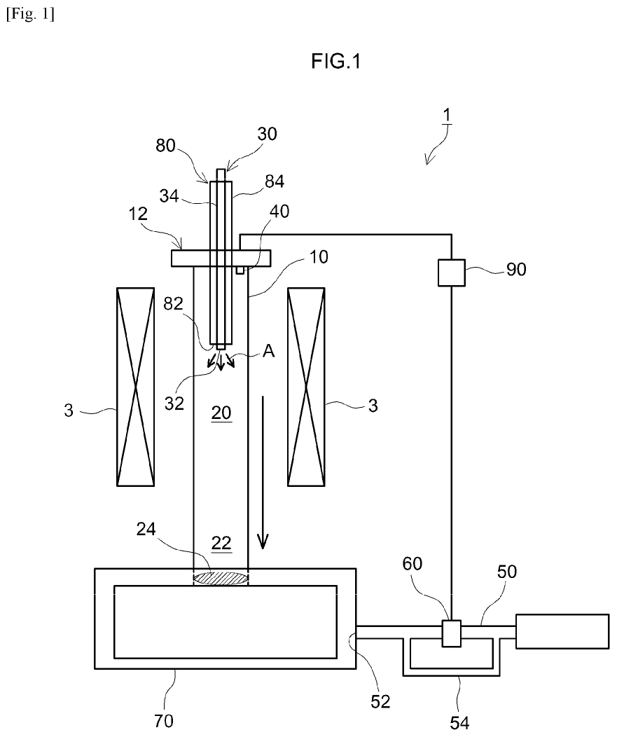

A preferred embodiment of the CNT production apparatus disclosed herein will be described with reference to the drawings. As shown in FIG. 1, a CNT production apparatus 1 according to the present embodiment is a CNT production apparatus that generates CNT in a gas phase flowing therethrough. This apparatus 1 includes a cylindrical chamber 10, a carbon source supply unit 30 that supplies a carbon source A to the chamber 10 from a carbon source supply port 32 opened to the chamber 10, a gas supply unit 80 that supplies a non-oxidizing gas to the chamber 10 from a gas supply port 82 opened to the chamber 10, a gas discharge pipe 50 configured to be capable of discharging gas located in the chamber 10, a control valve 60 provided to the gas discharge pipe 50, and a control unit 90 electrically connected to the control valve 60.

<Carbon Source Supply Unit>

The carbon source supply unit 30 is configured to supply (for example, spray) the carbon source A to the chamber 10 from the carbon source supply port 32 opened to the chamber 10. In this embodiment, the carbon source supply unit 30 includes a carbon source introduction pipe 34 extending in the below-described reaction zone 20 in the chamber 10 and connected to the carbon source supply port 32. The carbon source supply port 32 provided at the tip of the carbon source introduction pipe 34 is open to the reaction zone 20 or in the vicinity thereof. The carbon source supply port 32 provided at the tip of the carbon source introduction pipe 34 is open to the upstream side of the chamber 10. By configuring the carbon source A to be supplied directly to the reaction zone 20 (high-temperature region) in this manner, it is possible to gasify (evaporate) the carbon source (typically liquid) A, which is supplied from the carbon source supply port 32, in a short time and generate CNT from the carbon source A more efficiently. Further, by using the carbon source introduction pipe 34, it is possible to transfer the heat of the reaction zone 20 from the carbon source supply port 32 to the carbon source (liquid) A in the introduction pipe 34 through the wall surface of the carbon source introduction pipe 34, so as to gasify the carbon source A, which is supplied from the carbon source supply port 32, in a short time.

Various carbon (C)-containing materials capable of generating CNT by a CVD method can be used as the carbon source in the technique disclosed herein. A carbon source that is in the form of a liquid at room temperature (25° C.) is preferred. For example, aromatic hydrocarbons such as toluene, benzene, xylene, naphthalene, anthracene and tetralin, acyclic saturated aliphatic hydrocarbons such as hexane, heptane, octane, nonane, decane, undecane, dodecane, tridecane, tetradecane, pentadecane, hexadecane and heptadecane, cyclic saturated aliphatic hydrocarbons such as decalin, cyclohexane, hexane and tetradecahydrophenanthrene, mixtures thereof, and the like can be used as the carbon source. It is preferable to use a carbon source having a high carbon content. For example, toluene, benzene, or the like can be preferably used as the carbon source. These carbon sources are preferable in that they can be gasified (evaporated) in a short time after being supplied from the carbon source supply port 32 to the reaction zone 20 of the chamber 10.

The carbon source supply unit 30 can supply a catalytic metal or a catalytic metal compound together with the carbon source from the carbon source supply port 32 to the chamber 10. As the catalytic metal, one or two or more metals capable of catalyzing thermal decomposition of a carbon source (for example, toluene) in the CVD method can be used. For example, it is possible to use one or two or more selected from iron (Fe), cobalt (Co), nickel (Ni), scandium (Sc), titanium (Ti), vanadium (V), chromium (Cr), manganese (Mn), molybdenum (Mo), ruthenium (Ru), copper (Cu), and the like as the catalytic metal. It is preferable to use at least one of Fe and Co. This results in a product of better quality. Further, it is possible to further increase the CNT generation rate. The catalytic metal compound can be exemplified by an organic transition metal compound, an inorganic transition metal compound, and the like. Examples of the organic transition metal compound include ferrocene, nickelocene, cobaltocene, iron carbonyl, iron acetylacetonate, iron oleate, and the like. Among them, ferrocene is preferably used.

The carbon source supply unit 30 can supply a sulfur compound together with the carbon source and catalytic metal from the carbon source supply port 32 to the chamber 10. The sulfur compound can be exemplified by an organic sulfur compound, an inorganic sulfur compound, and the like. Examples of the organic sulfur compound include sulfur-containing heterocyclic compounds such as thiophene, thianaphthene and benzothiophene. Examples of the inorganic sulfur compound include hydrogen sulfide and the like. Among them, thiophene is preferably used. As a result, it is possible to further increase the generation rate of CNT by interaction with the catalytic metal.

<Gas Supply Unit>

The gas supply unit 80 is configured to supply a non-oxidizing gas (carrier gas) to the chamber 10 from the gas supply port 82 opened to the chamber 10. In this embodiment, the gas supply unit 80 is provided with a gas supply pipe 84 extending in the reaction zone 20 and connected to the gas supply port 82. The gas supply port 82 provided at the tip of the gas supply pipe 84 is opened to the reaction zone 20 or in the vicinity thereof. The gas supply port 82 provided at the tip of the gas supply pipe 84 is opened on the upstream side of the chamber 10.

A non-oxidizing gas is suitable as the carrier gas to be supplied from the gas supply port 82 to the chamber 10. In other words, it is preferable to use one or two or more selected from a reducing gas and an inactive gas as the carrier gas. Examples of the reducing gas include hydrogen (H2) gas, ammonia (NH3) gas, and the like. Examples of the inactive gas include argon (Ar) gas, nitrogen (N2) gas, helium (He) gas and the like. In a preferred embodiment of the production method disclosed herein, a reducing gas (for example, H2 gas) is used as the carrier gas.

Further, the non-oxidizing gas supplied from the gas supply port 82 to the chamber 10 may include a carbon source gas which is gaseous at room temperature. A substance that is thermally decomposed at a lower temperature than the carbon source supplied from the carbon source supply port 32 to the chamber 10 is preferable as the carbon source gas. A carbon source gas having such properties can be exemplified by an unsaturated aliphatic hydrocarbon such as ethylene and propylene having a double bond, and acetylene having a triple bond. A mixture thereof may also be used as the carbon source gas. By using such a carbon source gas in combination with the above-described liquid carbon source, it is possible to efficiently generate CNT having uniformly controlled diameter (for example, about 2 nm or less, typically about 1 nm to 2 nm).

In a preferred embodiment, the gas supply unit 80 and the carbon source supply unit 30 have a double-pipe structure in which the gas supply pipe 84 is an outer pipe and the carbon source introduction pipe 34 is an inner pipe. In other words, the gas supply port 82 provided at the tip of the gas supply pipe 84 and the carbon source supply port 32 provided at the tip of the carbon source introduction pipe 34 are disposed concentrically. In this example, the carbon source supply port 32 provided at the tip of the carbon source introduction pipe 34 protrudes downstream (downward) from the gas supply port 82 provided at the tip of the gas supply pipe 84. Such a configuration is advantageous for gasifying (evaporating) and diffusing the liquid of the carbon source supplied from the carbon source supply port 32 when a material that is liquid at room temperature is used as the carbon source. That is, as a result of forming the double-pipe structure with the gas supply pipe 84 as the outer pipe and the carbon source introduction pipe 34 as the inner pipe, the non-oxidizing gas supplied from the gas supply port 82 comes into contact with the carbon source (liquid) supplied from the carbon source supply port 32 and the gasification and diffusion of the carbon source (liquid) are promoted. As a consequence, the gasified carbon source can be better dispersed in the reaction zone 20. Therefore, CNT of higher quality can be generated efficiently (for example, in high yield).

<Gas Discharge Pipe>

The gas discharge pipe 50 is configured to be capable of discharging the gas in the chamber 10 from a gas release port 52 disposed downstream of the below-described deposition zone 22 of the chamber 10. In this embodiment, the gas release port 52 of the gas discharge pipe 50 is opened on a side surface of a below-described recovery unit (recovery container) 70 connected to the downstream side (lower side) of the chamber 10. Further, the control valve 60 is provided in the intermediate section of the gas discharge pipe 50. The control valve (for example, electromagnetic valve) 60 is electrically connected to the control unit 90 and configured to be opened and closed under the control of the control unit 90. The control valve 60 is controlled to be in the closed state during normal use (that is, during CNT production). Then, when recovering the CNT described hereinbelow, the valve is switched from the closed state to the open state. Further, in this embodiment, the gas discharge pipe 50 is provided with a bypass pipe 54 not passing through the control valve 60. As a result, even when the control valve 60 is closed, a certain amount of gas is discharged from the gas release port 52 through the bypass pipe 54. In a preferred embodiment, an adequate balance is set between the amount of the non-oxidizing gas (carrier gas) supplied from the gas supply port 82 to the chamber 10 and the amount of gas (other than the carrier gas; can include reaction gas generated by thermal decomposition of the carbon source, an unreacted carbon source, and the like) discharged from the gas release port 52 through the bypass pipe 54 in a state where the control valve 60 is closed, thereby making it possible to control the movement of the gasified carbon source so that the gasified carbon source diffuses neither to the upstream side nor the downstream side of the reaction zone 20 (in other words, so that the gasified carbon source is retained in the reaction zone 20).

<Chamber>

The chamber 10 is typically formed in a straight tubular shape (that is, such that the axis extends linearly) and preferably has a rounded cross-sectional shape, such as circular, elliptical, egg-shaped and oval. Alternatively, the cross-sectional shape may be polygonal (preferably having six or more sides, for example, six to twenty sides). The inner diameter and the length of the chamber 10 can be appropriately set in consideration of a desired CNT production capacity, facility cost, and the like. From the viewpoint of efficiently generating CNT, the CNT production apparatus disclosed herein can be preferably implemented in a mode using a cylindrical body having an inner diameter, for example, of about 50 mm to 500 mm Usually, it is preferable to set the inner diameter of the chamber 10 to about 50 mm to 200 mm The length of the chamber 10 can be about 1 time or more (typically about 1 to 10 times) the inner diameter. The length of the chamber 10 in the apparatus 1 of the present embodiment is about 1400 mm, and of these, the length of the reaction zone 20 is about 800 mm and the length of the deposition zone 22 is about 400 mm A material having heat resistance matching the CNT generation temperature and high chemical stability can be appropriately used as the constituent material of the chamber 10. Ceramics are a particularly preferable material. The opening on the upstream side of the chamber 10 is closed by an upstream lid 12. Meanwhile, the downstream end of the chamber 10 is in an open state.

<Reaction Zone>

The reaction zone 20 is heated to a temperature at which CNT are generated in the chamber 10. In this embodiment, a partial range of the chamber 10 in the cylinder axis direction (here, the upper portion and the center portion) is surrounded by the heater 3, and a portion located inside the enclosed region serves as the reaction zone 20. Any heater 3 may be used as long as it can heat the reaction zone 20 to a temperature suitable for the generation of CNT (typically about 500° C. to 2000° C., preferably about 1000° C. to 1600° C., for example about 1100° C. to 1200° C.), and the shape and heating method thereof are not particularly limited. An electric furnace is an example of the heater 3 that can be advantageously used. In the present embodiment, two electric furnaces having a substantially semicircular cross-sectional shape are used as the heater 3, and these electric furnaces are set opposite to each other so as to surround a partial range of the chamber 10. By heating the reaction zone 20 to the temperature at which CNT are generated, the carbon source supplied from the carbon source supply port 32 is gasified (vaporized), and the thermally decomposed to generate CNT.

<Deposition Zone>

The deposition zone 22 is provided downstream of the reaction zone 20 in the chamber 10 and serves to cool and deposit generated CNT 24. That is, the CNT 24 produced by thermally decomposing the carbon source in the reaction zone 20 move to the deposition zone 22 and are cooled and typically deposited near the outlet of the chamber 10. Accordingly, the vicinity of the outlet of the chamber 10 is gradually thickly covered with the CNT 24. A cooling mechanism (for example a water-cooled jacket) for forcibly cooling the deposition zone 22 may be disposed around the deposition zone 22. In this way, the CNT 24 can be efficiently deposited in the deposition zone 22. As a result of thus thickly covering the deposition zone 22 downstream of the reaction zone 20 with the CNT (and eventually bringing it close to the blocked state), the gasified carbon source is likely to stay in the reaction zone 20 (that is, diffusion to the downstream side of the reaction zone 20 is suppressed). It is therefore possible to generate high-quality CNT from the carbon source more efficiently (for example, in high yield). Further, the CNT deposited in the deposition zone 22 can be recovered by switching the above-described control valve (electromagnetic valve) 60 to an open state. That is, when the control valve 60 is switched to the open state, a large amount of high-pressure gas (gasified carbon source and non-oxidizing gas) retained in the reaction zone 20 passes through the deposition zone 22 and the below-described recovery unit 70 and is released from the gas release port 52. With this gas flow, the CNT deposited in the deposition zone 22 can be moved to the recovery unit 70 and recovered in the recovery unit 70.

<Deposition State Detector>

A deposition state detector 40 is configured to detect the physical property value indicating the deposition state of the CNT in the deposition zone 22. The deposition state detector 40 is not particularly limited as long as it can detect the physical property value indicating the deposition state of the CNT. In this embodiment, the deposition state detector 40 is a pressure sensor 40. Thus, when the deposition zone 22 is thickly covered with CNT and approaches a blocked state, since the gasified carbon source and the non-oxidizing gas remain in the reaction zone 20, the pressure in the chamber 10 rises. Therefore, by measuring the pressure in the chamber 10, it is possible to ascertain the deposition state of CNT in the deposition zone 22. The pressure sensor 40 may be disposed on the upstream side of the deposition zone 22. In this embodiment, the pressure sensor 40 is attached to the lower surface of the upstream lid 12 that closes the upstream side of the chamber 10.

<Recovery Unit>

The apparatus 1 according to the present embodiment is provided with a recovery unit 70 that recovers the CNT sent from the deposition zone 22 to the downstream side when the control valve 60 is switched to the open state. The recovery unit 70 is disposed downstream of the deposition zone 22 and upstream of the gas release port 52. In this way, it is possible to efficiently recover the CNT while the discharge gas moves from the deposition zone 22 to the gas release port 52. In this embodiment, the recovery unit 70 is a recovery container 70. The gas release port 52 is opened on a side surface of the recovery container 70. Further, the recovery container 70 is connected to the downstream end of the chamber 10 in a state where the upper side is open. That is, the recovery container 70 is disposed below the deposition zone 22 in a state where the upper side is open. Further, when the control valve 60 is switched to the open state, the CNT deposited in the deposition zone 22 is caused to fall into the recovery container 70. By causing the CNT to fall under gravity in this way, it is possible to recover the CNT more efficiently. The recovery unit 70 may be provided with a trapping mechanism such as a mesh steel so that the CNT could be easily recovered.

<Control Unit>

The control unit 90 is configured to close the control valve 60 and deposit CNT in the deposition zone 22 when the physical property value (here, the internal pressure of the chamber 10) indicating the deposition state of the CNT detected by the deposition state detector (in this example, the pressure sensor) 40 is equal to or less than a predetermined threshold value. Further, when the physical property value indicating the deposition state of the CNT exceeds the predetermined threshold value, the control valve 60 is opened and the CNT deposited in the deposition zone 22 are moved to the recovery unit 70 and recovered in the recovery unit 70. A typical configuration of the control unit 90 includes at least a ROM (Read Only Memory) that stores a program for performing such control, a CPU (Central Processing Unit) that can execute the program, a RAM (random access memory) that temporarily stores data, and an input/output port (not shown). The control unit 90 inputs various signals (output) and the like from the deposition state detector (pressure sensor) 40 via an input port. Further, an opening/closing driving signal to the control valve 60 and the like are outputted from the control unit 90 via an output port. The ROM stores the threshold value of a pressure or the like which serves as a determination criterion for opening/closing the control valve.

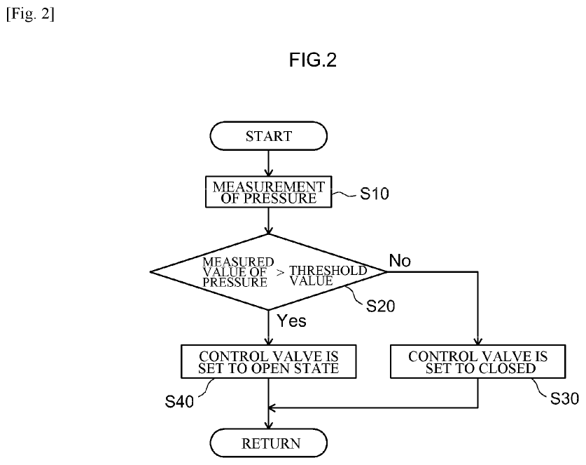

The operation of the CNT production apparatus 1 configured as described above will be described hereinbelow. FIG. 2 is a flowchart showing an example of a control valve opening/closing control processing routine executed by the CPU of the control unit 90 according to the present embodiment. This opening/closing control processing routine is repeatedly executed at predetermined time intervals immediately after the apparatus 1 is actuated.

When the processing routine shown in FIG. 2 is executed, the control unit 90 firstly reads a signal inputted from the pressure sensor 40 and measures the pressure in the chamber 10 in step S10. Next, in step S20, it is determined whether or not the measured value of the pressure measured by the pressure sensor 40 exceeds a predetermined threshold value. When the measured value of the pressure measured by the pressure sensor 40 does not exceed the predetermined threshold value (the case of “NO”), the control unit 90 determines that it is not the time to recover the CNT deposited in the deposition zone 22, the process proceeds to step S30, and the control valve 60 is set to a closed state. As a result, CNT are deposited in the deposition zone 22. In the state where CNT are deposited in the deposition zone 22, the gasified carbon source remains in the reaction zone 20 better, so that high-quality CNT can be efficiently generated.

Meanwhile, when the measured value of the pressure measured by the pressure sensor 40 exceeds the predetermined threshold value (the case of “YES”), the control unit 90 determines that it is the time to recover the CNT deposited in the deposition zone 22, the process proceeds to step S40, and the control valve 60 is set to an open state. As a result, the CNT deposited in the deposition zone 22 move to the downstream side together with the gas flow and are recovered in the recovery unit 70. In this way, the CNT deposited in the deposition zone 22 can be recovered at an appropriate timing. The process then returns to the start again, and the operations from step S10 to step S40 are thereafter repeated.

With the apparatus 1, by closing the control valve 60 and causing the deposition (typically, the adhesion to the inner wall of the chamber) of CNT in the deposition zone 22, it is possible to retain more favorably a carbon source in the reaction zone 20 upstream of the deposition zone 22 (that is, suppress the diffusion to the downstream side of the reaction zone 20), and it is possible to efficiently generate high-quality CNT from the carbon source (for example, in high yield). Also, the CNT can be continuously produced by opening the control valve 60 and recovering the CNT deposited in the deposition zone 22 when the deposition of CNT proceeds to some extent in the deposition zone 22. That is, the apparatus 1 having the above-described configuration is suitable for continuous production of CNT.

According to the technique disclosed herein, it is possible to provide a method for producing carbon nanotubes by which carbon nanotubes are produced by supplying a carbon source and a non-oxidizing gas to the cylindrical chamber 10.

In the method, with the chamber 10 being provided with the reaction zone 20 which is provided in a partial range of the chamber 10 in the direction of the cylinder axis and heated to a temperature at which carbon nanotubes are generated; the deposition zone 22 which is provided downstream of the reaction zone 20 and upstream of the gas release port 52 for releasing gas in the chamber 10 and in which the generated carbon nanotubes are cooled and deposited; and a deposition state detector 40 which detects a physical property value indicating a deposition state of the carbon nanotubes in the deposition zone 22,

the method including the steps of:

closing the control valve 60 of the gas discharge pipe 50 connected to the gas release port 52 and depositing carbon nanotubes in the deposition zone 22 when the physical property value indicating the deposition state of carbon nanotubes in the deposition zone 22 is equal to or less than a predetermined threshold value (deposition step); and

opening the control valve 60 and recovering the carbon nanotubes deposited in the deposition zone 22 when the physical property value exceeds the predetermined threshold value (recovery step).

With such a method, high-quality CNT can be obtained continuously and efficiently (for example, in high yield) by repeating the deposition step and the recovery step.

### Second Embodiment

The opening and closing control of the control valve executed in the CNT production apparatus 1 according to the embodiment of the present invention has been described hereinabove. Next, opening and closing control of a control valve executable by the CNT production apparatus 1 according to another embodiment of the present invention will be described.

This embodiment differs from the above-described First Embodiment in that the physical property value indicating the deposition state of CNT in the deposition zone 22 of the chamber 10 is the deposition amount of CNT calculated from the image of the deposition zone 22 captured by an image capturing device 40.

That is, in this embodiment, the deposition state of the CNT is directly grasped using the image capturing device 40. The image capturing device 40 can be used without particular limitation as long as the image of the periphery of the deposition zone 22 can be captured with high resolution from the outside of the chamber 10. For example, a known image capturing device (camera) using a CCD image sensor, a CMOS image sensor, or the like can be used. The image capturing device 40 picks up the deposition state of the CNT in the deposition zone 22 in the process of producing the CNT as imaging data and transmits the imaging data to the control unit 90. In a preferred embodiment, the image capturing device 40 is configured to capture the image of the deposition zone 22 from the direction (for example, the image capturing device 40 is disposed on the upstream lid 12 of the chamber 10 and oriented downward from this position) orthogonal to the CNT deposition direction (the radial direction of the chamber 10). In this way, it is possible to more accurately capture the image of the deposition state of the CNT deposited in the deposition zone 22. Further, the image capturing device 40 is configured to capture the image of the deposition zone 22 continuously (over time) in the process of producing the CNT. The image capturing device 40 continuously (over time) picks up the deposition state of the CNT in the deposition zone 22 as imaging data, and continuously (over time) transmits the imaging data to the control unit 90. Incidentally, the term “continuously” as used herein is inclusive of not only a mode in which image capturing is performed without interruption, but also a mode in which image capturing is continuously performed intermittently at regular time intervals.

With the abovementioned configuration, it is possible to grasp the deposition state of the CNT deposited in the deposition zone 22 more directly and accurately. Therefore, it is possible to recover at an appropriate timing the CNT deposited in the deposition zone 22.

Although specific examples of the present invention have been described in detail hereinabove, these examples are merely illustrative and do not limit the scope of the claims. Techniques set forth in the claims include those in which the specific examples exemplified above are variously modified and changed.

For example, in the above-described embodiments, the physical property value indicating the deposition state of the CNT in the deposition zone 22 of the chamber 10 is exemplified by the pressure in the chamber 10 measured by the pressure sensor and the deposition amount of CNT calculated from the image of the deposition zone 22 captured by the image capturing device. However, the physical property value indicating the deposition state of CNT in the deposition zone 22 is not limited to these values. For example, the deposition state of CNT may be grasped by a physical property value such as a temperature in the chamber 10.

Further, in the embodiments, the recovery container 70 is provided below the chamber 10, but the recovery container 70 may be omitted. Furthermore, the material of the chamber 10 constituting the CNT production apparatus 1 is not limited to ceramics, as in the embodiment, and it goes without saying that the materials can be changed as appropriate. In addition, the specific features such as the shapes of the chamber 10, the carbon source introduction pipe 34, the gas supply pipe 84, the heater 3, and the recovery container 70 can also all be arbitrarily designed and changed within the range intended by the present invention.

### INDUSTRIAL APPLICABILITY

The present invention can provide a apparatus and a method for efficiently producing CNT by using the CVD method.

1. A method for producing carbon nanotubes, the method comprising the following steps of:
supplying a carbon source and a non-oxidizing gas from a supply unit of a double-pipe structure in which a gas supply pipe is an outer pipe and a carbon source introduction pipe is an inner pipe to a cylindrical chamber;
generating carbon nanotubes by heating a reaction zone provided in a direction of cylinder axis of the chamber to a temperature at which carbon nanotubes are generated;
depositing the carbon nanotubes generated in the generating step in a deposition zone;
detecting a physical property value indicating a deposition state of the carbon nanotubes deposited in the depositing step by a deposition state detector; and
recovering the carbon nanotubes deposited in the deposition zone based on the physical property value indicating the deposition state of the carbon nanotubes by the deposition state detector; wherein,
the deposition zone is located downstream of the reaction zone and upstream of a gas release port for releasing gas in the chamber,
closing a control valve of a gas discharge pipe connected to the gas release port when the physical property value indicating the deposition state of carbon nanotubes in the deposition zone is equal to or less than a predetermined threshold value and
opening the control valve and recovering the carbon nanotubes deposited in the deposition zone when the physical property value exceeds the predetermined threshold value.

2. The production method according to claim 1, wherein
a carbon source supply port provided at a tip of the carbon source introduction pipe protrudes downward from a gas supply port provided at a tip of the gas supply pipe.

3. The production method according to claim 1, wherein
in the step of supplying the carbon source and the non-oxidizing gas, the non-oxidizing gas supplied from a gas supply port and the carbon source supplied from a carbon source supply port are brought into contact with each other.

4. The production method according to claim 1, wherein
in the step of supplying the carbon source and the non-oxidizing gas, a catalytic metal or a catalytic metal compound is supplied to the chamber together with the carbon source.

5. The production method according to claim 1, wherein
the physical property value indicating the deposition state of the carbon nanotubes is a pressure in the chamber.

6. The production method according to claim 1, wherein
the physical property value indicating the deposition state of CNT in the deposition zone of the chamber is a deposition amount of CNT calculated from an image of the deposition zone captured by an image capturing device.

7. The production method according to claim 6, wherein
in the step of detecting a physical property value, the image capturing device captures the image of the deposition zone from the direction orthogonal to the radial direction of the chamber.

8. The production method according to claim 6, wherein
the image capturing device is a CCD image sensor.

9. The production method according to claim 6, wherein
the image capturing device is a CMOS image sensor.

10. The production method according to claim 1, wherein
in the step of generating the carbon nanotubes, the reaction zone is heated from 1110° C. to 1200° C.

11. The production method according to claim 1, wherein
a recovery unit is disposed below the chamber, and
in the step of recovering the carbon nanotubes, the carbon nanotubes deposited in the deposition zone are caused to fall into the recovery unit.

12. The production method according to claim 1, further comprising
cooling the deposition zone by a cooling mechanism, after the step of generating the carbon nanotubes.

13. The production method according to claim 12, wherein
the cooling mechanism is a water-cooled jacket.
